(19) United States
(12) Patent Application Publication
(10) Pub. No.: US 2006/0157198 A1
(43) Pub. Date: Jul. 20, 2006

(54) Member for plasma processing apparatus and plasma processing apparatus

(76) Inventors: Muneo Furuse, Kudamatsu (JP); Masanori Kadotani, Kudamatsu (JP); Hiroho Kitada, Kudamatsu (JP); Shingo Kimura, Shuunan (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/065,084

(22) Filed: Feb. 25, 2005

(30) Foreign Application Priority Data
Jan. 17, 2005 (JP) 2005-008604

(51) Int. Cl. H01L 21/306; C23F 1/00; C23C 16/00

(52) U.S. Cl. 156/345.24; 118/723 R; 156/345.42; 156/914; 118/723 MA

(57) ABSTRACT

Provided is a plasma processing apparatus, which comprises, as a member facing plasma in a plasma processing chamber, a member composed of a material prepared by incorporating a conductive material in quartz or germanium which is an amorphous base material.

### CLAIM OF PRIORITY

The present application claims priority from Japanese Application JP 2005-008604 filed on Jan. 17, 2005, the content of which is hereby incorporated by reference into this application.

### FIELD OF THE INVENTION

The present invention relates to a plasma processing apparatus, more specifically, a plasma processing apparatus suited for stably generating a plasma in a vacuum chamber.

### BACKGROUND OF THE INVENTION

Such a plasma processing apparatus has, on the upper side of a processing chamber placed in a vacuum chamber, an antenna-like radio source for emitting radiation, and on the bottom of the processing chamber, a lower electrode over which a sample (ex. a wafer) to be processed is set. By the interaction between the radiation from the antenna-like radio source and a magnetic field from a magnetic field generating unit placed as needed, a processing gas fed into the processing chamber is converted into plasma. Also known is an apparatus for controlling the action of ions or radicals in plasma by a bias power from a bias power source connected to a lower electrode, thereby processing a thin film formed over a wafer.

In such a plasma processing apparatus, it is the common practice to suppress etching of the surface of the wall of the processing chamber or the surface of the material of electrode member by plasma during processing or consumption of it by the reaction. As such a related art, a plasma processing apparatus disclosed in Japanese Patent Laid-Open No. 2001-057361 is known. In this apparatus, the surface of a metal material at a ground portion (earth portion) for plasma generated in the processing chamber and having a potential is covered with alumina (Al₂O₃) which is relatively resistant to etching by plasma.

In the apparatus as described in Japanese Patent Laid-Open No. 2001-226773, the processing chamber has an inner surface covered with a film containing a compound of a group 3a element of the periodic table.

The related art is however accompanied with the problem that when alumina or a compound of a group 3a element of the periodic table is used as a grounded electrode (earth of plasma), a substance composed of such a material is formed, and it diffuses and adheres onto a wafer and finally, has an adverse effect on the processing results.

In the above-described related art, therefore, a material to be used in the processing chamber must have reliability and stability when it is used as a grounded electrode for providing a ground potential for plasma generated in the processing chamber. Described specifically, when the material is used as a grounded electrode for plasma generated in the processing chamber, ions in the plasma of a gas used for processing are incident to the member and collide with the surface of material or they react with particles of the grounded electrode emitted upon impact to form a chloride or fluoride. When a compound of such substances is deposited on the inner surface of the processing chamber and forms a film with a certain thickness, it peels off from the inner surface of the processing chamber, adheres onto the wafer as a particles, and has an adverse effect on the processing.

When the grounded electrode is sputtered by ions, the element emitted from the grounded electrode inevitably becomes a metal contamination source on the wafer. Materials used as a grounded electrode are therefore required to have improved stability and reliability of processing by reducing the adverse effect on the wafer caused by the action between the earth surface and plasma. As miniaturization of devices, a further reduction in such an adverse effect brought by a particles source or contamination source is demanded.

Without using another material instead of a material used for a grounded electrode of the conventional plasma processing apparatus, it is difficult to maintain an earth potential while suppressing emission of a heavy metal from the chamber wall upon etching or sputtering during plasma processing. The grounded electrode for determining a plasma potential must be a conductor. Conductors tend to be made of a metal causing a defect in the element structure on a wafer to be treated and a metal-containing substance is detected as a contamination source when it reaches the wafer.

As a measure for reducing such an adverse influence, on the wafer, of particles or contamination derived from a conductive member constituting the grounded electrode, use of silicon or a compound thereof, or carbon or a compound thereof which has less influence can be considered as a material constituting the grounded electrode. It has however a problem that a grounded electrode made of such a material, as well as a wafer to be processed, tends to cause reaction with plasma generated in the processing chamber or tends to be etched, which shortens the lifetime of the grounded electrode, the replacement cycle shortens and as a result, lowers the processing efficiency.

### SUMMARY OF THE INVENTION

An object of the present invention is to provide a plasma processing apparatus capable of reducing the influence of a material constituting a processing chamber on the processing of a sample (ex. a wafer for a semiconductor device) to be processed, thereby improving the stability and reliability of the processing.

In the present invention, there is thus provided a plasma processing apparatus for processing a sample with plasma by controlling the generation of the plasma in a processing chamber and an incident energy of ions to the sample, respectively, wherein the processing chamber is made of a material formed by containing a conductive material in a base material of quartz or germanium which is an amorphous material.

Material of highly resistant to plasma include materials using quartz, materials obtained by sintering ceramics such as alumina, and materials formed by plasma spraying of ceramic powder such as alumina powder. Since these materials have no conductivity, it is difficult to use them as a base material for a grounded electrode which is formed in the processing chamber and determines the potential of plasma. In the case of a material obtained by plasma spraying of ceramic powder, the material itself does not have conductivity but, upon excitation of plasma, it has a function as a grounded electrode for plasma thus generated when a resistance of the plasma-sprayed material per unit area satisfies the following equation: t/kε≦300 wherein kε represents a specific dielectric constant of a material to be plasma-sprayed relative to radio frequency wave to be excited, and t represents the thickness (μm) of the plasma-sprayed material.

When a grounded electrode is formed by uniformly mixing silicon or a compound thereof, or carbon or a compound thereof which is a conductor, in a quartz material or sintered ceramics such as sintered alumina, the material of the grounded electrode itself must have strength. When the material of the grounded electrode has, for example, a thickness of 3 mm or greater, a dielectric constant of the material itself must be increased in order to provide the base material such as quartz material or sintered ceramics with a function of a grounded electrode.

The dielectric constant of the grounded electrode can be increased by using, as a base material of the grounded electrode, a quartz material or sintered ceramics such as sintered alumina and uniformly mixing therein a metal, silicon or a compound thereof, or carbon or a compound thereof which is a conductor. The quartz constituting the ground is made of an amorphous material and the above-described conductive material is mixed uniformly all over the amorphous portion. This quartz is preferably vitreous.

Similar effects can be brought about by using an oxide of a rare earth metal or an oxide made of at least three elements containing a rare earth metal instead of the sintered ceramics such as sintered alumina. Use of a high melting point metal such as rare earth metal which is a conductor makes it possible to constitute a material which hardly discharge a metal even exposed to plasma. By adopting such a constitution, scattering and adhesion of a substance, which will otherwise be a contamination source, to a wafer is suppressed even by processing with plasma, leading to improvements in reliability and stability of processing.

The present invention is thus effective for facilitating the prevention of metal contamination by placing a member acting as a grounded electrode, obtained by incorporating a conductor in quartz or sintered ceramics such as alumina ceramics.

### BRIEF DESCRIPTION OF THE DRAWINGS

FIG. 1 is a cross-sectional view illustrating a plasma etching apparatus which is one embodiment of the present invention; and

FIG. 2 is a cross-sectional view illustrating a lower electrode portion of a plasma etching apparatus which is another embodiment of the present invention.

### DETAILED DESCRIPTION OF THE INVENTION

In the present invention, a member inside of a processing chamber of a plasma processing apparatus which gives etching or other processing to a sample (ex. a semiconductor wafer, a wafer for a semiconductor device) to be processed using plasma is made of a material hard to cause adhesion of particles or generation of contamination derived from the material constituting the capable of serving as an earth which gives plasma a reference potential in the processing chamber. In the processing chamber, it is therefore important to prevent a material, which is brought into contact with plasma, from being a contamination source or a source of particles; and to allow the contact surface with plasma to serve as a grounded electrode for earth.

A material which does not easily become a source for contamination or particles such as elements of a gas to be used for etching or elements of a material to be etched is suited as the material to be used in the processing chamber. Even if a material contains a substance which will be a contamination source or particles, an etched amount by sputtering or a reaction amount with plasma can be reduced when it is obtained by incorporating a high melting point metal such as rare earth metal in a quartz material or sintered ceramics such as sintered alumina. This makes it possible to place the ground portion in the processing chamber in the vicinity of the wafer to stabilize the potential or current between the lower electrode on which the wafer is placed and the grounded electrode, or between plasma and the grounded electrode, thereby stabilizing the processing itself.

In the plasma processing apparatus according to this embodiment, a portion to be brought into contact with plasma in the processing chamber is made of a member obtained by using an amorphous material or vitreous material made of quartz or germanium (Ge) which is a highly plasma resistant material and uniformly incorporating, in this highly plasma resistant material, a conductor such as silicon, carbon, or a compound thereof. This makes it possible to cause quartz or alumina to act on plasma and serve, for example, as an electrode, leading to reliable and stable processing, which will otherwise be disturbed by the adhesion of contaminants such as heavy metals or particles, or adhesion of the reaction products containing metals, each generated from the contact surface with plasma and having an adverse effect on the performance of a semiconductor device available by the processing of a wafer.

In addition, by using such a material having conductivity and plasma resistance as a member in the processing chamber, diffusion of plasma, which has been generated in the processing chamber, to the outside of the processing chamber to seek for a grounded electrode (earth potential) can be suppressed. As a result, radio frequency power can be transmitted in the stabilized state to plasma generated in the processing chamber.

Moreover, it is possible to avoid difficulty in widening the interval necessary for exchange of the grounded electrode or member in the processing chamber to a predetermined value or greater, because when a material obtained by incorporating a conductor in a plasma-resistant material is formed by plasma spraying, the material to be plasma-sprayed must have a thickness not greater than a predetermined value in order to impart it with an earth function.

This makes it possible to reduce the amount of particles or contamination on the wafer to be processed, suppress the production amount of defective semiconductor elements available by the processed wafer and to improve a production yield, which leads to an improvement in the total processing efficiency and operation efficiency of the processing apparatus.

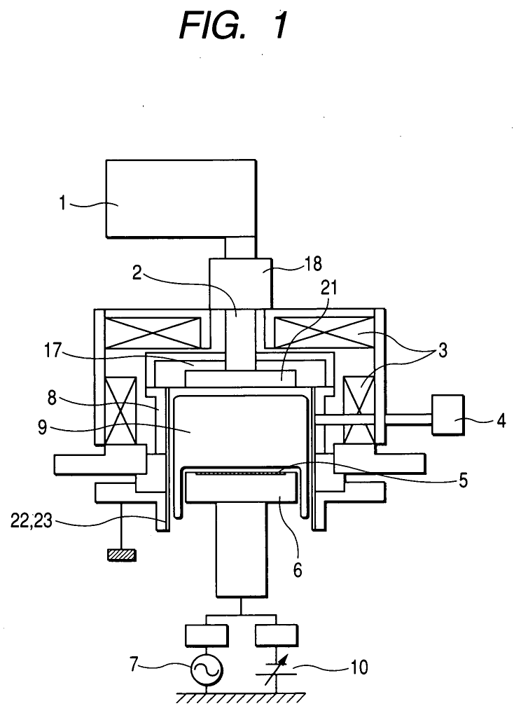

One embodiment of the present invention will next be described referring to FIG. 1.

FIG. 1 illustrates a plasma etching apparatus according to one embodiment of the present invention. The plasma etching apparatus employed here is an ECR system one which emits an electromagnetic wave from an antenna and generates plasma 9 by the interaction with a magnetic field. A plasma processing chamber, which is an etching chamber 8 in this drawing, is designed to control its inner wall surface temperature to fall within a range of from 20 to 100° C. by a temperature controller which is not illustrated here. On the upper side of the etching chamber 8, an antenna 21 is placed. Between the etching chamber 8 and antenna 21, a dielectric substance 17 capable of transmitting an electromagnetic wave therethrough is disposed. In this case, a radio frequency power source 1 for generating a UHF electromagnetic wave is connected to the antenna 21 via a waveguide tube 2 and a matching box 18. The etching chamber 8 is, at the periphery thereof, wound with a magnetic field coil 3 for forming a magnetic field in the etching chamber 8.

Below the antenna 21 in the etching chamber 8, a lower electrode 6 having a flat portion on the upper surface of which a wafer 5 is to be placed is disposed. To this lower electrode 6, a power source 7 of a radio frequency bias power for giving an incident energy to ions in plasma, which is to be used for processing the wafer 5, and a DC power source 10 for forming a potential to adsorb the wafer 5 to the above-described upper surface (flat portion) of the lower electrode 6 by an electrostatic force are connected.

The etching chamber 8 is made of a metal and it is grounded at a substantially cylindrical side wall portion thereof. On the inner wall surface of this side wall portion, an amorphous material of member 22 obtained by incorporating carbon, silicon or a compound thereof, which is a conductor, in a quartz material or sintered ceramics such as sintered alumina, which is a plasma resistant material, laid.

In this embodiment, the amorphous material of member 22 made of quartz and containing a conductor is a member having, as a base material, an amorphous material, preferably a vitreous material, especially preferably silica glass. Particles of the above-described carbon, silicon, or a compound thereof having conductivity, or a metal or a compound thereof are dispersed uniformly all over the base material.

In silica glass, atoms are bonded in the amorphous form instead of orderly tetrahedral orientations of SiO₄ observed in crystalline silica such as quartz or cristobalite.

As a preparation process of silica glass, heating and melting method or dry synthetic method is known. In the heating and melting method, natural quartz is heated at a temperature as high as about 2000° C. to form molten quartz in which bonds of tetrahedral SiO₄ units have been broken, followed by cooling to re-combine the tetrahedral SiO₄ units at random. In the dry synthesizing process, on the other hand, silicon tetrachloride (SiCl₄) is hydrolyzed at from 1000 to 1200° C. in an oxyhydrogen flame of high temperature to form tetrahedral SiO₄ units with loose bonding and then the resulting units are molten by heating at 1800° C. or greater, followed by cooling to recombine the tetrahedral SiO₄ units at random.

In this embodiment, an amorphous material of member having conductivity is formed in accordance with the above-described process by heating and melting natural quartz and particles having conductivity.

In such a constitution, the amorphous material of member 22 is brought into contact, at one portion thereof, with the etching chamber 8 inside thereof, and serves as a grounded electrode, becoming an earth potential for plasma 9. When a rare earth metal or a compound thereof is used as the conductor to be incorporated in the quartz material, it does not matter to use one or more of scandium, yttrium, lanthanum, cerium, praseodymium, neodymium, promethium, samarium, europium, gadolinium, terbium, dysprosium, holmium, erbium, thulium, ytterbium, and lutetium.

According to this embodiment, an amorphous material of member obtained by uniformly mixing carbon, silicon or compound thereof in quartz, germanium, or sintered ceramics such as sintered alumina is used as a material of a portion which faces plasma inside of the etching chamber. This makes it possible to suppress the supply, onto the wafer, of a metal having an adverse effect on the performance of elements formed by processing with plasma. As a result, a problem such as contamination, which will otherwise occur by the adhesion of a substance having an adverse effect such as a heavy metal, can be inhibited. In addition, inhibition of the contamination on the surface of the wafer 5 leads to an improvement in the productivity of a semiconductor device.

Instead of the amorphous material of member 22 made of quartz, an amorphous material made of a semiconductor such as Ge can be used.

When such a constitution is adopted, supply, to the inside wall or inside bottom of the etching chamber in the vicinity of the wafer 5, with a substance such as metal having an adverse effect on the structure or performance of a semiconductor device formed by the plasma etching can be suppressed, whereby occurrence frequency of a problem such as contamination by a metal can be reduced.

A second embodiment of the plasma etching apparatus according to the present invention is similar to that illustrated in FIG. 1 except for the use of ceramics 23 obtained by incorporating a conductive material in sintered ceramics such as sintered alumina instead of the amorphous material of member 22. When an oxide of a rare earth metal is employed for the ceramics in which the conductive material is to be incorporated, a sintered material composed of one or more oxides of a rare earth metal selected from the group consisting of scandium, yttrium, lanthanum, cerium, praseodymium, neodymium, promethium, samarium, europium, gadolinium, terbium, dysprosium, holmium, erbium, thulium, ytterbium, and lutetium may be used and as the conductive material, carbon, silicon or the like may be used. When a rare earth metal or a compound thereof is used as the conductor to be incorporated in the ceramics, one or more of scandium, yttrium, lanthanum, cerium, praseodymium, neodymium, promethium, samarium, europium, gadolinium, terbium, dysprosium, holmium, erbium, thulium, ytterbium, and lutetium may be used.

According to this embodiment, a material obtained by uniformly mixing carbon, silicon or a compound thereof in quartz or Ge which is an amorphous material or sintered ceramics such as sintered alumina is used as a member at a portion facing plasma of the etching chamber. This makes it possible to suppress the supply, onto the wafer, a metal having an adverse effect on the performance of the device formed by processing with the plasma. As a result, a problem such as contamination which will otherwise occur by the adhesion of a substance having an adverse effect such as heavy metal can be inhibited. In addition, inhibition of the contamination on the surface of the wafer 5 leads to an improvement in the productivity of a semiconductor device.

When a rare earth metal is used for the conductor to be incorporated in the quartz amorphous material of member 2 or sintered ceramics such as sintered alumina, an amount of the metal released in the plasma processing chamber owing to the etching of a grounded electrode by plasma generated in the etching chamber is small because the rare earth metal has a large atomic weight and has a high melting point. As a result, the amount of a metal scattering to the wafer used for the manufacture of devices is small, whereby an object of reducing a metal contamination amount can be attained.

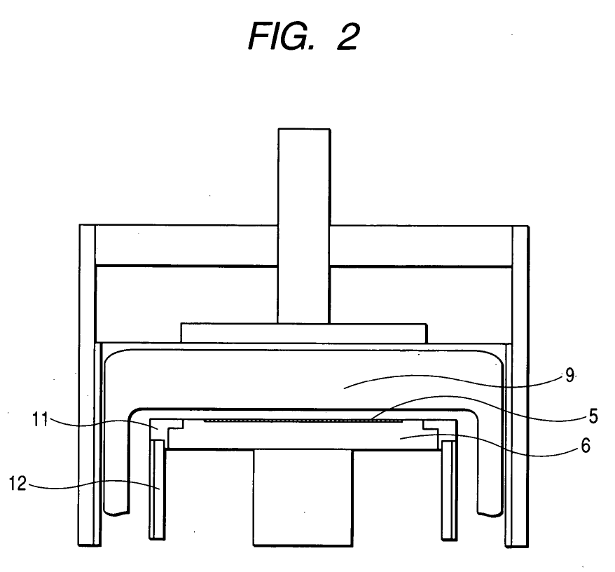

In the above-described two embodiments, the etching chamber 8 having an inner wall surface covered with the quartz amorphous material of member 22 or ceramics 23 was described. As illustrated in the example of FIG. 2, the lower electrode 6 on which a wafer used for the manufacture of devices is placed may be covered with an electrode cover 12 disposed via an insulating cover 11.

What is claimed is:

1. A plasma processing apparatus for processing a sample by controlling generation of plasma in a processing chamber and an incident energy of ions to said sample separately, the plasma processing apparatus comprises;
a member facing the plasma in the processing chamber, wherein said member being made of a material obtained by incorporating a conductive material in an amorphous base material composed of quartz or germanium.

2. A plasma processing apparatus according to claim 1,
wherein at least one of carbon, carbon compounds, silicon and silicon compounds is used as the conductive material.

3. A plasma processing apparatus according to claim 1, wherein one or more rare earth metals or compounds thereof are used as the conductive material, said rare earth metal being selected from the group consisting of scandium, yttrium, lanthanum, cerium, praseodymium, neodymium, promethium, samarium, europium, gadolinium, terbium, dysprosium, holmium, erbium, thulium, ytterbium, and lutetium.

4. A plasma processing apparatus according to any one of claims 1 to 3,
wherein the member is made of a material obtained by incorporating the conductive material in the base material which has been obtained by melting and then cooling the melt to solidify.
